(19) United States
(12) Patent Application Publication
(10) Pub. No.: US 2008/0218961 A1
(43) Pub. Date: Sep. 11, 2008

(54) HEAT DISSIPATION MODULE AND DESKTOP HOST USING THE SAME

(75) Inventors: Chih-Wei Wu, Taipei Hsien (TW); Chia-Yi Chang, Taipei Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: DFI, INC., Taipei Hsien (TW)

(21) Appl. No.: 11/747,232

(22) Filed: May 11, 2007

(30) Foreign Application Priority Data
Mar. 5, 2007 (TW) 96107472

(51) Int. Cl. H05K 7/20

(52) U.S. Cl. 361/687; 361/709

(57) ABSTRACT

A heat dissipation module suitable for a desktop host includes a case, a power supply with a fan, and a mother board. The power supply and the mother board are disposed in the case. The mother board includes a work components. The heat dissipation module includes a first heat sink, a second heat sink and a heat pipe. The first heat sink is disposed on the work components. The second heat sink is disposed outside the case and at the outlet port of the fan. The heat pipe is connected between the first heat sink and the second heat sink. Hence, the heat dissipation module can dissipate the heat generated by the work component.

### CROSS-REFERENCE TO RELATED APPLICATION

This application claims the priority benefit of Taiwan application serial no. 96107472, filed Mar. 5, 2007. All disclosure of the Taiwan application is incorporated herein by reference.

### BACKGROUND OF THE INVENTION

1. Field of the Invention

The present invention is generally related to a computer and a heat dissipation module thereof, and more particularly, to a desktop host and a heat dissipation module used on the same.

2. Description of Related Art

There are many work components on a mother board of a desktop host. Some of the work components, for example, a Central Processing Unit (CPU), a Pulse Width Modulation (PWM), and a north bridge chip, etc., generate a large amount of heat when operating, and therefore increase the temperature thereof.

If the heat is not timely dissipated, the temperature of the work components will increase gradually and exceed their work temperature. Such a situation results in a temporary failure of the work components rendering the operation of the desktop host unstable. An extremely high temperature of the work components may even result in a permanent failure of the work components.

Generally, in order to decrease the temperature of the work components during operation thereof, heat sinks are disposed on the work components, especially on the central processing unit, the pulse width modulation, and the north bridge chip, etc., respectively. In addition, fans may further be mounted on the heat sinks, especially on the heat sinks on the central processing unit and the north bridge chip, respectively. Consequently, the heat dissipation efficiency of the heat sinks can be increased by the air stream provided by the fans.

Thus, the temperature of the work components can be reduced to avoid temporary or permanent failure. However, the noises, especially the high frequency noises generated by the operation of the fans may make users feel uncomfortable.

### SUMMARY OF THE INVENTION

The present invention provides a heat dissipation module suitable for decreasing the temperature of work components in a desktop host.

The present invention provides a heat dissipation module having an advantage of low noise.

The present invention provides a desktop host, a heat dissipation module suitable for decreasing the temperature of work components in the desktop host.

The present invention provides a desktop host, a heat dissipation module having an advantage of low noise.

The present invention discloses a heat dissipation module suitable for a desktop host which includes a case, a power supply with a fan, and a mother board. The power supply and the mother board are disposed in the case. The mother board includes work components. The heat dissipation module includes at least a first heat sink, a second heat sink and a first heat pipe. The first heat sink is disposed on one of the work components. The second heat sink is disposed outside the case and at the outlet port of the fan. The first heat pipe is connected between the first heat sink and the second heat sink.

In an embodiment of the present invention, the above-mentioned heat dissipation module further includes first heat sinks and second heat pipes. The first heat sinks are disposed on the work components respectively, and the first heat pipe is connected between one of the first heat sinks and the second heat sink. One of the second heat pipes is connected between two of the first heat sinks.

In an embodiment of the present invention, the first heat sinks are connected in series via the second heat pipes.

The present invention further discloses a heat dissipation module suitable for a desktop host which includes a case and a mother board. The mother board includes work components, one of which is a central processing unit. The heat dissipation module includes a water cooling device, at least a heat sink, and a first heat pipe. The water cooling device includes a heat exchanger, two pipes, and a water cooling head. The heat exchanger is disposed outside the case, and the water cooling head is disposed on the central processing unit. The pipes are connected between the water cooling head and the heat exchanger. The heat sink is disposed on one of the work components except the central processing unit. The first heat pipe is connected between the heat sink and the water cooling head.

In an embodiment of the present invention, the above-mentioned heat dissipation module further includes second heat pipes and heat sinks. The heat sinks are disposed on the work components except the central processing unit respectively, and the first heat pipe is connected between one of the heat sinks and the water cooling head. One of the second heat pipes is connected between two of the heat sinks.

In an embodiment of the present invention, the above-mentioned water cooling head and the heat sinks are connected in series via the first heat pipe and the second heat pipes.

The present invention further discloses a desktop host which includes a case, a power supply, a mother board and a heat dissipation module. The power supply with a fan and the mother board are disposed in the case. The mother board includes a circuit carrier and work components mounted on the circuit carrier. The heat dissipation module includes at least a first heat sink, a second heat sink, and a first heat pipe. The first heat sink is disposed on one of the work components, and the second heat sink is disposed outside the case and at the outlet port of the fan. The first heat pipe is connected between the first heat sink and the second heat sink.

In an embodiment of the present invention, the work components described above includes a central processing unit, a pulse width modulation, a south bridge chip, and a north bridge chip.

In an embodiment of the present invention, the above-mentioned first heat pipe is connected between the second heat sink and the first heat sink on the pulse width modulation.

In an embodiment of the present invention, the above-mentioned heat dissipation module further includes first heat sinks and second heat pipes. The first heat sinks are disposed on the central processing unit, the pulse width modulation, the south bridge chip, and the north bridge chip, respectively. The first heat pipe is connected between one of the first heat sinks and the second heat sink, and one of the second heat pipes is connected between two of the first heat sinks.

In an embodiment of the present invention, the first heat sinks described above are connected in series via the second heat pipes.

The present invention further discloses a desktop host which includes a case, a mother board, and a heat dissipation module. The mother board is disposed in the case, and includes a circuit carrier and work components, one of which is central processing unit, mounted on the circuit carrier. The heat dissipation module includes a water cooling device, at least a heat sink, and a first heat pipe. The water cooling device includes a heat exchanger, two pipes, and a water cooling head. The heat exchanger is disposed outside the case, and the water cooling head is disposed on the central processing unit. The pipes are connected between the water cooling head and the heat exchanger. The heat sink is disposed on one of the work components except the central processing unit. The first heat pipe is connected between the heat sink and the water cooling head.

In an embodiment of the present invention, the work components described above include a pulse width modulation, a south bridge chip, and a north bridge chip.

In an embodiment of the present invention, the above-mentioned heat dissipation module further includes heat sinks and second heat pipes. The heat sinks are disposed on the pulse width modulation, the south bridge chip, and the north bridge chip, respectively, and the first heat pipe is connected between one of the heat sinks and the water cooling head. One of the second heat pipes is connected between two of the heat sinks.

In an embodiment of the present invention, the above-mentioned first heat pipe is connected between the water cooling head and the heat sink on the pulse width modulation.

In an embodiment of the present invention, the above-mentioned water cooling head and the heat sinks are connected with each other in series via the first heat pipe and the second heat pipes.

In the present invention, the heat generated by the work components is dissipated to outside surroundings by using the second heat sink, which is disposed at the outlet port of the fan of the power supply, or the water cooling device, so as to decrease the temperature of the work components. Further, the present invention has the advantage of low noise because the number of fans in the present invention is few compared to the prior art.

These and other embodiments, features, aspects, and advantages of the present invention will be described and become more apparent from the detailed description of embodiments when read in conjunction with accompanying drawings.

### BRIEF DESCRIPTION OF THE DRAWINGS

FIG. 1 is a schematic diagram of a desktop host according to an embodiment of the present invention.

FIG. 2 is a schematic diagram of a desktop host according to another embodiment of the present invention.

### DESCRIPTION OF EMBODIMENTS

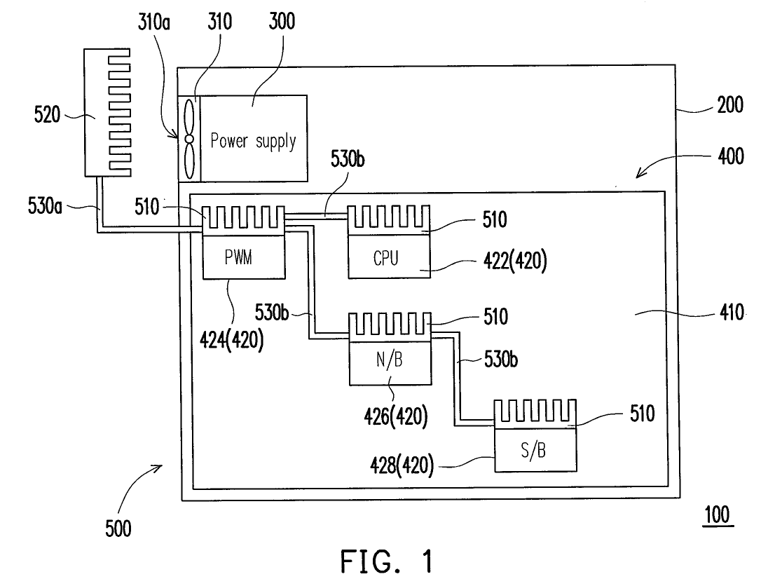

FIG. 1 is a schematic diagram of a desktop host according to an embodiment of the present invention. Referring to FIG. 1, the desktop host 100 includes a case 200, a power supply 300, a mother board 400 and a heat dissipation module 500. The power supply 300 is disposed in the case 200, and has a fan 310. The mother board 400 is disposed in the case 200, and includes a circuit carrier 410 and work components 420 mounted on the circuit carrier 410.

The heat dissipation module 500 includes first heat sinks 510, a second heat sink 520, and a first heat pipe 530a. The first heat sinks 510 are disposed on the work components 420, respectively. The second heat sink 520 is disposed outside the case 200 and at the outlet port 310a of the fan 310. The first heat pipe 530a is connected between one of the first heat sinks 510 and the second heat sink 520.

In this embodiment, the heat dissipation module 500 may further include second heat pipes 530b, one of which being connected between two of the first heat sinks 510. Thus, the heat generated by the work components 420 may be transferred to the second heat sink 520 via the first heat sinks 510, the second heat pipes 530b, and the first heat pipe 530a. Because the second heat sink 520 is disposed outside the case 200 and at the outlet port 310a of the fan 310, the heat dissipation efficiency of the second heat sink 520 can be increased by the air stream provided by the fan 310. Therefore, the heat generated by the work components 420 may be rapidly dissipated from the second heat sink 520. Thus, the work components 420 share the second heat sink 520 at the outlet port 310a to decrease the temperature, such that the desktop host 100 can operate steadily.

The work components 420 may include a central processing unit 422, a pulse width modulation 424, a north bridge chip 426, and a south bridge chip 428. And the first heat sinks 510 may be disposed on the central processing unit 422, the pulse width modulation 424, the north bridge chip 426, and the south bridge chip 428, respectively. In this embodiment, the first heat pipe 530a is connected between the second heat sink 520 and the first heat sink 510 on the pulse width modulation 424. Sure, in other unshown embodiments, the first heat pipe 530a may also be connected between the second heat sink 520 and the respective first heat sink 510 disposed on one of the central processing unit 422, the north bridge chip 426, and the south bridge chip 428.

Thus, the temperature of the central processing unit 422, the pulse width modulation 424, the north bridge chip 426, and the south bridge chip 428 may be reduced to avoid temporary or permanent failure such that the desktop host 100 can operate steadily. In addition, in this embodiment, as shown in FIG. 1, the first heat sinks 510 may be connected in series through the second heat pipes 530b.

It should be understood that in other unshown embodiments, another heat dissipation module may also include a first heat sink 510 disposed on one of the work components 420, without the second heat pipes 530b. Therefore, the first heat pipe 530a may be only connected between one first heat sink 510 and one second heat sink 520.

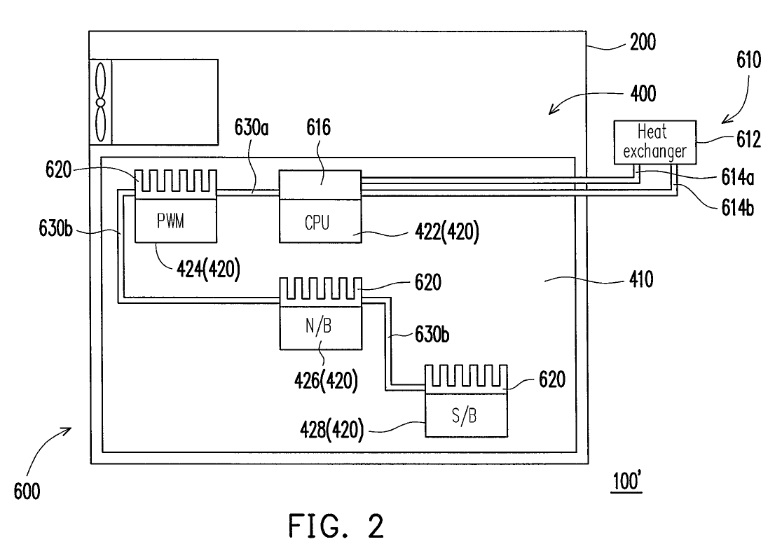

FIG. 2 is a schematic diagram of a desktop host according to another embodiment of the present invention. Referring to FIG. 2, the desktop host 100′ includes a case 200, a mother board 400, and a heat dissipation module 600. The mother board 400 is disposed in the case 200, and includes a circuit carrier 410 and work components 420 mounted on the circuit carrier 410. The work components 420 may include a central processing unit 422, a pulse width modulation 424, a north bridge chip 426, and a south bridge chip 428.

The desktop host 100′ of the present embodiment is similar to the aforementioned desktop host 100 of the above embodiment. However, a primary difference between the two is the heat dissipation module 600. Specifically, the heat dissipation module 600 includes a water cooling device 61 0, heat sinks 620, and a first heat pipe 630a. The water cooling device 610 includes a heat exchanger 612, two pipes 614a and 614b, and a water cooling head 616. The heat exchanger 612 is disposed outside the case 200. The water cooling head 616 is disposed on the central processing unit 422, and the pipes 614a and 614b are connected between the water cooling head 616 and the heat exchanger 612.

The water cooling device 610 of the present embodiment further includes a cooling fluid, which may be water or other suitable liquid, and the heat exchanger 612 may include a pump and a water cooler ( the pump, the cooling fluid, and the water cooler are not shown in FIG. 2). The pump may drive the cooling fluid to flow between the water cooling head 616 and the heat exchanger 612 via the pipes 614a and 614b to remove the heat generated by the central processing unit 422.

Particularly, the heat generated by the central processing unit 422 will be transferred to the cooling fluid in the water cooling head 616 to rise the temperature thereof. Next, the cooling fluid with increased temperature is driven by the pump, and flows from the water cooling head 616 to the water cooler of the heat exchanger 612 via the pipe 614a. The heat of the cooling fluid is dissipated to the outside surroundings by the water cooler to reduce the temperature of the cooling fluid. Thereafter, the cooling fluid with reduced temperature is driven by the pump, and flows from the heat exchanger 612 back to the water cooling head 616 via the pipe 614b. Thus, the cooling fluid can circulate between the water cooling head 616 and the heat exchanger 612 to reduce the temperature of the central processing unit 422.

The heat sinks 620 are disposed on the work components except the central processing unit 422. For example, the heat sinks 620 are disposed on the pulse width modulation 424, the north bridge chip 426, and the south bridge chip 428, respectively. The first heat pipe 630a is connected between one of the heat sinks 620 and the water cooling head 616. In the present embodiment, the first heat pipe 630a is connected between the water cooling head 616 and the heat sink 620 on the pulse width modulation 424. Sure, in other unshown embodiments, the first heat pipe 630a may also be connected between the water cooling head 616 and the heat sink 620 on the north bridge chip 426 or the south bridge chip 428.

Also, the heat dissipation module 600 further includes second heat pipes 630b, one of which is connected between two of the heat sinks 620. In relation to the manner of the connection of the second heat pipes 630b with the heat sinks 620, the heat sinks 620 and the water cooling head 616 may be connected in series via the first heat pipe 630a and the second heat pipes 630b, as shown in FIG. 2.

Because one of the second heat pipes 630b is connected between two of the heat sinks 620, and the first heat pipe 630a is connected between one of the heat sinks 620 and the water cooling head 616, the heat generated by the central processing unit 422, the pulse width modulation 424, the north bridge chip 426, and the south bridge chip 428 may be transferred to the water cooling head 616 via the heat sinks 620 and the second heat pipes 630b. Next, the water cooling head 616 transfers the heat to the water cooler of the heat exchanger 612 through the cooling fluid. Thus, the work components 420 may share one water cooling device 610 to reduce temperature, such that the desktop host 100′ can operate steadily.

It should be understood that in other unshown embodiments, another heat dissipation module may also include one heat sink 620, which is disposed on the pulse width modulation 424, the north bridge chip 426, or the south bridge chip 428, without including the second heat pipes 630b. Therefore, the first heat pipe 630a may only be connected between one of the heat sinks 620 and the water cooling head 616.

Therefore, in the present invention, the heat generated by work components in a desktop host may be dissipated to outside surroundings by using a second heat sink at the outlet port of a fan of a power supply or a water cooling device for originally cooling the central processing unit, to reduce the temperature of the work components, such that the desktop host can operate steadily.

In addition, in the present invention, only the fan of the power supply or the water cooling device for originally cooling the central processing unit is utilized as a common heat dissipation source to reduce the temperature of the work components. Consequently, compared to a conventional art, the number of fans in the present invention is reduced, so there is an advantage of low noise.

While the present invention has been particularly shown and described with reference to embodiments thereof, it will be understood by those of ordinary skill in the art that various changes in form and details may be made therein without departing from the spirit and scope of the present invention as defined by the following claims.

What is claimed is:

1. A heat dissipation module, suitable for a desktop host including a case, a power supply with a fan, and a mother board, wherein the power supply and the mother board are disposed in the case, and the mother board includes a plurality of work components, the heat dissipation module comprising:
at least a first heat sink, disposed on one of the plurality of work components;
a second heat sink, disposed outside the case and at the outlet port of the fan; and
a first heat pipe, connected between the first heat sink and the second heat sink.

2. The heat dissipation module of claim 1, further including a plurality of first heat sinks and a plurality of second heat pipes, wherein the plurality of first heat sinks are disposed on the plurality of work components respectively, the first heat pipe is connected between one of the first heat sinks and the second heat sink, and one of the plurality of second heat pipes is connected between two of the first heat sinks.

3. The heat dissipation module of claim 2, wherein the plurality of first heat sinks are connected in series via the plurality of second heat pipes.

4. A heat dissipation module suitable for a desktop host including a case and a mother board, wherein the mother board includes a plurality of work components, one of which is a central processing unit, the heat dissipation module comprising:
a water cooling device, comprising a heat exchanger, two pipes and a water cooling head, wherein the heat exchanger is disposed outside the case, the water cooling head is disposed on the central processing unit, and the pipes are connected between the water cooling head and the heat exchanger;
at least a heat sink, disposed on one of the plurality of the work components except the central processing unit; and
a first heat pipe, connected between the heat sink and the water cooling head.

5. The heat dissipation module of claim 4, further including a plurality of second heat pipes and a plurality of heat sinks, wherein the plurality of heat sinks are disposed on the plurality of work components except the central processing unit respectively, the first heat pipe is connected between one of the heat sinks and the water cooling head, and one of the plurality of second heat pipes is connected between two of the heat sinks.

6. The heat dissipation module of claim 5, wherein the water cooling head and the plurality of heat sinks are connected in series via the first heat pipe and the plurality of second heat pipes.

7. A desktop host, comprising:
a case;
a power supply, disposed in the case, wherein the power supply comprises a fall;
a mother board, disposed in the case and comprising a circuit carrier and a plurality of work components mounted on the circuit carrier; and
a heat dissipation module, comprising:
at least a first heat sink, disposed on one of the plurality of work components;
a second heat sink, disposed outside the case and at the outlet port of the fan; and
a first heat pipe, connected between the first heat sink and the second heat sink.

8. The desktop host of claim 7, wherein the plurality of work components include a central processing unit, a pulse width modulation, a south bridge chip, and a north bridge chip.

9. The desktop host of claim 8, wherein the first heat pipe is connected between the second heat sink and the first heat sink on the pulse width modulation.

10. The desktop host of claim 8, wherein the heat dissipation module further includes a plurality of first heat sinks and a plurality of second heat pipes, wherein the plurality of first heat sinks are disposed on the central processing unit, the pulse width modulation, the south bridge chip, and the north bridge chip respectively, the first heat pipe is connected between one of the first heat sinks and the second heat sink, and one of the plurality of second heat pipes is connected between two of the first heat sinks.

11. The desktop host of claim 10, wherein the plurality of first heat sinks are connected in series via the plurality of second heat pipes.

12. A desktop host, comprising:
a case;
a mother board, disposed in the case and comprising a circuit carrier and a plurality of work components mounted on the circuit carrier, wherein one of the plurality of work components is a central processing unit; and
a heat dissipation module, comprising:
a water cooling device, comprising a heat exchanger, two pipes and a water cooling head, wherein the heat exchanger is disposed outside the case, the water cooling head is disposed on the central processing unit, and the pipes are connected between the water cooling head and the heat exchanger;
at least a heat sink, disposed on one of the plurality of work components except the central processing unit; and
a first heat pipe, connected between the heat sink and the water cooling head.

13. The desktop host or claim 12, wherein the plurality of work components includes a pulse width modulation, a south bridge chip and a north bridge chip.

14. The desktop host of claim 13, wherein the heat dissipation module further includes a plurality of heat sinks and a plurality of second heat pipes, wherein the plurality of heat sinks are disposed on the pulse width modulation, the south bridge chip and the north bridge chip respectively, the first heat pipe is connected between one of the heat sinks and the water cooling head, and one of the plurality of second heat pipes is connected between two of the heat sinks.

15. The desktop host of claim 14, wherein the first heat pipe is connected between the water cooling head and the heat sink on the pulse width modulation.

16. The desktop host of claim 14, wherein the water cooling head and the plurality of heat sinks are connected in series via the first heat pipe and the plurality of second heat pipes.
